(19) United States
(12) Patent Application Publication
(10) Pub. No.: US 2006/0284318 A1
(43) Pub. Date: Dec. 21, 2006

(54) Semiconductor device and method for fabricating the same

(76) Inventors: Tomohiro Murata, Osaka (JP); Yutaka Hirose, Kyoto (JP); Yasuhiro Uemoto, Shiga (JP); Tsuyoshi Tanaka, Osaka (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 11/436,722

(22) Filed: May 19, 2006

(30) Foreign Application Priority Data
Jun. 15, 2005 (JP) 2005-174859

(51) Int. Cl. H01L 23/52

(52) U.S. Cl. 257/758

(57) ABSTRACT

According to a method for fabricating a semiconductor device, a first semiconductor layer made of a first nitride semiconductor is formed over a substrate. Thereafter, a mask film covering part of the upper surface of the first semiconductor layer is selectively formed on the first semiconductor layer. A multilayer film, in which second and third nitride semiconductors having different band gaps are stacked, is selectively formed on the first semiconductor layer with the mask film used as a formation mask. On the multilayer film, an ohmic electrode is formed.

### CROSS-REFERENCE TO RELATED APPLICATION

This application claims priority under 35 USC § 119 to Japanese Patent Application No. 2005-174859 filed on Jun. 15, 2005, the entire contents of all of which are incorporated herein by reference.

### BACKGROUND OF THE INVENTION

1. Field of the Invention

The present invention relates to Group III-V nitride semiconductor devices and methods for fabricating the same, and more particularly relates to transistors for use as high-frequency devices.

2. Description of the Related Art

Nitride semiconductors are made of gallium nitride (GaN), aluminum nitride (AlN), indium nitride (InN), or other mixed crystal expressed by a general formula (InₓAl₁₋ₓ)_{y}Ga_{1-y}N (0≦x≦1, 0≦y≦1). Applications of the nitride semiconductors not only to optical semiconductor devices but also to electron devices are being examined. In the application to optical semiconductor devices, physical features of the nitride semiconductors, i.e., the wide band gap and the direct band gap, are utilized, while in the application to electron devices, other features thereof, which are high breakdown field and high saturation electron velocity, are utilized. In particular, hetero-junction field effect transistors (hereinafter referred to as “HFETs”), which uses 2-dimensional electron gas (hereinafter referred to as “2DEG”) appearing at the interface between AlₓGa₁₋ₓN and GaN epitaxially grown on a semi-insulating substrate, are being developed as high-power high-frequency devices.

In these nitride semiconductor devices, parasitic resistance components such as contact resistance and channel resistance must be reduced as much as possible. A method for reducing contact resistance of an ohmic electrode has been proposed, in which the ohmic electrode is formed on a superlattice layer composed of stacked AlGaN and GaN layers (see Japanese Laid-Open Publication No. 2005-26671, for example).

However, when a superlattice layer composed of AlGaN and GaN layers is used as a contact layer, it is very difficult to form a recess structure, where a gate electrode is formed.

In cases where a contact layer formed of a typical GaN layer is used, if selective etching is applied to the contact layer existing on an AlGaN layer serving as a barrier layer, it is possible to automatically stop the etching at the surface of the barrier layer.

However, in the case of the superlattice layer, selective etching is not applicable, because the superlattice layer is composed of the AlGaN and GaN layers. It is thus difficult to automatically stop the etching at the surface of the barrier layer, and therefore the contact layer must be etched by time control. In that case, variations in the etching rate from wafer to wafer or within a single wafer surface cause the recess depth to be changed, which leads to a problem in that characteristic values such as threshold voltage are varied.

Even in cases where variations in the etching rate can be suppressed, if variations in the crystal growth rate and the like cause the thickness of the contact layer to be varied from wafer to wafer or within a single wafer surface, the depth of the recess is changed to thereby produce a problem in that characteristic values such as threshold voltage are varied.

In particular, in cases where an n-type doped layer is placed in the vicinity of the interface between the barrier layer and the contact layer to achieve further reduction in the contact resistance, if etching for forming the recess is insufficient, the highly doped n-type layer is left under the gate electrode to cause the problem of increase in the gate leakage current.

### SUMMARY OF THE INVENTION

It is therefore an object of the present invention to solve the above problems and to realize a semiconductor device in which a multilayer film composed of aluminum gallium nitride layers and gallium nitride layers is used as a contact layer and therefore the contact resistance is small and variations in characteristic values such as threshold voltage are small, and a method for fabricating the semiconductor device.

In order to achieve the above object, according to the present invention, the contact layer composed of the multilayer film is formed after a mask is selectively formed on a barrier layer.

More specifically, an inventive method for fabricating a semiconductor device includes the steps of: (a) forming a first semiconductor layer made of a first nitride semiconductor over a substrate; (b) selectively forming, on the first semiconductor layer, a mask film covering part of the upper surface of the first semiconductor layer; (c) selectively forming, on the first semiconductor layer, a multilayer film with the mask film used as a formation mask, the multilayer film including stacked second and third nitride semiconductors having different band gaps; and (d) forming an ohmic electrode on the multilayer film.

According to the inventive method, to form a gate-recess structure, etching of the multilayer film serving as a contact layer is not necessary. Therefore, the depth of the recess is uniform, which enables fabrication of semiconductor devices in which variations in characteristic values such as threshold voltage are small.

In the inventive method, the mask film is preferably a single layer film made of one compound selected from the group consisting of silicon dioxide, silicon oxynitride, and silicon nitride or a multilayer film in which two or more compounds selected from the group are stacked. This structure allows the growth of the multilayer film to be masked reliably.

The inventive method preferably further includes: the step of removing the mask film to expose the part of the upper surface of the first semiconductor layer, after the step (c) is performed; and the step of forming a Schottky electrode on the exposed part of the upper surface of the first semiconductor layer.

The inventive method preferably further includes: between the step (b) and the step (c), the step of selectively forming, on the first semiconductor layer, a second semiconductor layer made of an n-type doped fourth nitride semiconductor, with the mask film used as a formation mask. By this structure, it is possible to further reduce the contact resistance of the ohmic electrode. In addition, since the n-type semiconductor layer is not formed in the gate electrode formation region, there is no n-type impurity under the gate electrode. Therefore, increase in the gate leakage current is prevented.

The inventive method preferably further includes: between the step (b) and the step (c), the step of selectively implanting ions of an n-type impurity into the first semiconductor layer with the mask film used as an implantation mask; and the step of performing a heat treatment for activating the implanted n-type impurity ions. In this structure, it is also possible to further reduce the contact resistance of the ohmic electrode. Also, since the mask film is used as the impurity-ion implantation mask, almost no increase is required in the number of process steps. In this case, the n-type impurity is preferably silicon.

The inventive method preferably further includes: between the step (b) and the step (c), the step of selectively etching the first semiconductor layer with the mask film used as an etching mask, thereby forming a recess in an upper portion in the first semiconductor layer, wherein in the step (c), the multilayer film is preferably formed on the bottom of the recess. By this structure, the thickness of the first semiconductor layer serving as a barrier layer can be reduced to thereby permit contact resistance to be lowered further.

The inventive method preferably further includes: the step of forming, over the substrate, a third semiconductor layer made of a fifth nitride semiconductor whose band gap is smaller than that of the first nitride semiconductor, before the step (a) is performed, wherein in the step (a), the first semiconductor layer is preferably formed on the third semiconductor layer. This structure enables 2-dimensional electron gas to be produced between the first and third semiconductor layers, so that a semiconductor device that operates at high speed can be realized.

A first inventive semiconductor device includes: a substrate; a first semiconductor layer made of a first nitride semiconductor and formed over the substrate; a Schottky electrode formed in a region on the first semiconductor layer; a multilayer film formed in a region on the first semiconductor layer which is different from the Schottky electrode formation region and including stacked second and third nitride semiconductors having different band gaps; and an ohmic electrode formed on the multilayer film, wherein an n-type impurity concentration at an interface between the first semiconductor layer and the multilayer film is higher than that at a contact surface between the first semiconductor layer and the Schottky electrode.

In the first inventive semiconductor device, the contact resistance of the ohmic electrode can be reduced without causing any increase in leakage current from the Schottky electrode. It is therefore possible to realize semiconductor devices in which the contact resistance is small and characteristics such as threshold voltage are identical.

A second inventive semiconductor device includes: a substrate; a first semiconductor layer made of a first nitride semiconductor and formed over the substrate; a Schottky electrode formed in a region on the first semiconductor layer; a multilayer film formed in a region on the first semiconductor layer which is different from the Schottky electrode formation region and including stacked second and third nitride semiconductors having different band gaps; and an ohmic electrode formed on the multilayer film, wherein the thickness of part of the first semiconductor layer located under the ohmic electrode is smaller than the thickness of part of the first semiconductor layer located under the Schottky electrode.

In the second inventive semiconductor device, the contact resistance of the ohmic electrode is small. It is therefore possible to realize semiconductor devices in which the contact resistance is small and characteristics such as threshold voltage are identical.

In the first and second inventive semiconductor devices, two such multilayer films are preferably formed so as to be respectively located at both sides of the Schottky electrode; the ohmic electrode is preferably formed on each of the multilayer films; and the semiconductor device preferably functions as a field effect transistor.

The first and second inventive semiconductor devices each preferably further include a second semiconductor layer formed in contact with the lower surface of the first semiconductor layer and made of a fourth nitride semiconductor whose band gap is smaller than that of the first nitride semiconductor.

### BRIEF DESCRIPTION OF THE DRAWINGS

FIGS. 1A to 1D are cross-sectional views illustrating process steps for fabricating a semiconductor device according to a first embodiment of the present invention.

FIGS. 2A to 2D are cross-sectional views illustrating process steps for fabricating a semiconductor device according to a second embodiment of the present invention.

FIGS. 3A to 3D are cross-sectional views illustrating process steps for fabricating a semiconductor device according to a third embodiment of the present invention.

FIGS. 4A to 4D are cross-sectional views illustrating process steps for fabricating a semiconductor device according to a fourth embodiment of the present invention.

### DETAILED DESCRIPTION OF THE INVENTION

### First Embodiment

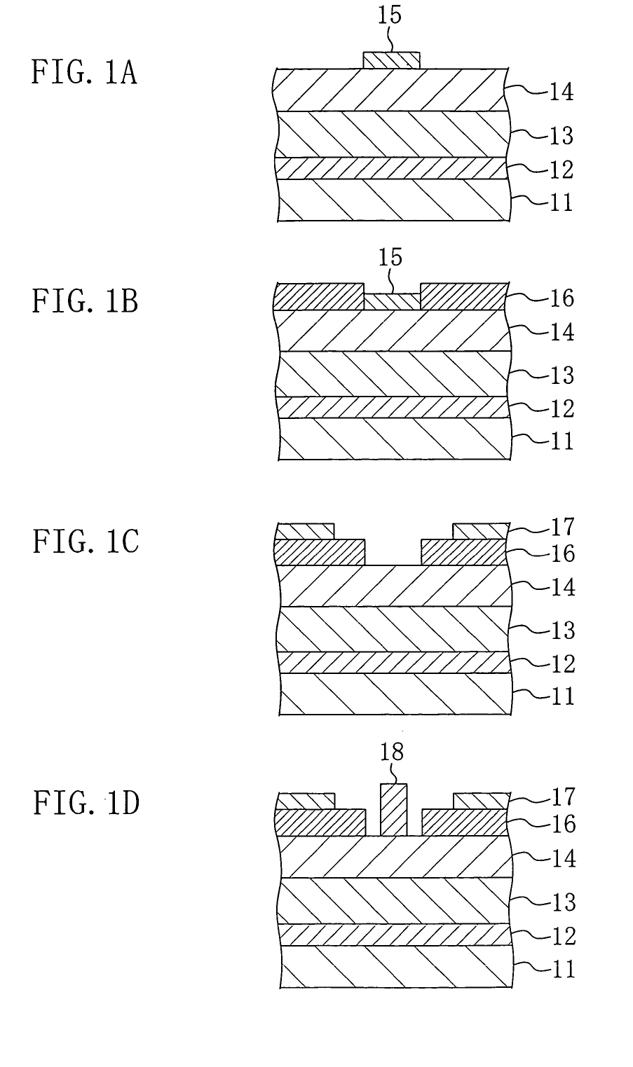

A first embodiment of the present invention will be described with reference to the accompanying drawings. FIG. 1 illustrates process steps for fabricating a semiconductor device according to the first embodiment of the present invention.

First, as shown in FIG. 1A, a buffer layer 12 made of AlN is formed on a sapphire substrate 11, and an active layer 13 made of GaN and a barrier layer 14 made of Al_{0.26}Ga_{0.74}N are formed on the buffer layer 12 in this order by a metal organic chemical vapor deposition (MOCVD) process. Subsequently, a mask film 15 made of silicon dioxide (SiO₂) is deposited on the barrier layer 14 and pattering is then performed by wet etching or dry etching so as to leave part of the mask film 15 located in a region in which a gate electrode is to be formed.

Next, as shown in FIG. 1B, Al_{0.26}Ga_{0.74}N and GaN films are epitaxially grown alternately on the barrier layer 14 seven times, i.e., seven Al_{0.26}Ga_{0.74}N films and seven GaN films are alternately grown, by an MOCVD process, thereby forming a multilayer film 16. Each Al_{0.26}Ga_{0.74}N film has a thickness of 5.6 nm and each GaN film has a thickness of 1.4 nm.

Then, as shown in FIG. 1C, the mask film 15 is removed by wet etching, and an ohmic electrode 17, in which titanium (Ti) and aluminum (Al) are stacked in this order, is then formed on the multilayer film 16.

Subsequently, as shown in FIG. 1D, an alloy (PdSi) of palladium and silicon, palladium (Pd), and gold (Au), for example, are stacked in this order on the barrier layer 14, thereby forming a gate electrode 18. The materials of the gate electrode are not limited to these, but known materials may be used.

In this embodiment, the multilayer film 16 is formed only in the region in which the ohmic electrode 17 is formed. This eliminates the need for etching of the multilayer film 16, thereby allowing very high repeatability of the thickness of the barrier layer 14 under the gate electrode 18. It is therefore possible to fabricate devices in which characteristic values such as threshold voltage are identical.

For the mask film 15, a silicon nitride (SiN) film or a silicon oxynitride (SiON) film may be used instead of the SiO₂ film. Alternatively, a multilayer film composed of at least two of SiO₂, SiN, and SiON films may be used.

Also, the multilayer film 16, in which the Al_{0.26}Ga_{0.74}N and GaN films are stacked, is used in this embodiment. However, for the multilayer film 16, any two kinds of nitride semiconductor films having different band gaps may be stacked so that 2DEG is produced at the interface of the multilayer film. The thicknesses of the nitride semiconductor films may be changed as necessary, and the number of the bilayers may be one or more.

Furthermore, the multilayer film 16 may be formed by stacking superlattice structures. For example, superlattice structures (called AlGaN/GaN superlattices) each composed of stacked AlGaN and GaN films, and superlattice structures (called GaN/InGaN superlattices) each composed of stacked GaN and InGaN films may be stacked to form the multilayer film 16.

Although in this embodiment the barrier layer 14 and part of the multilayer film 16 are both made of Al_{0.26}Ga_{0.74}N, they may be made of AlGaN in which the Al content is other than 0.26. Furthermore, the Al content in the AlGaN in the barrier layer 14 and that in the multilayer film 16 may be different from each other. Moreover, the barrier layer 14 and the part of the multilayer film 16 may be made of other nitride semiconductor than AlGaN.

Moreover, an n-type doped GaN layer may be formed on the multilayer film 16 and then the ohmic electrode 17 may be formed on the n-type doped GaN layer.

### Second Embodiment

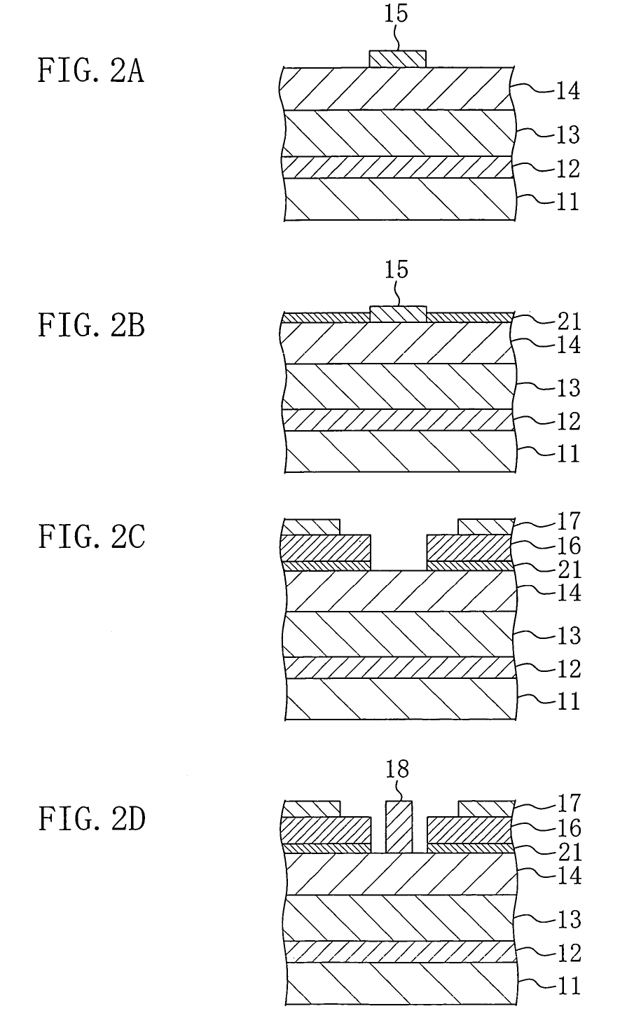

A second embodiment of the present invention will be described with reference to the accompanying drawings. FIG. 2 illustrates process steps for fabricating a semiconductor device according to the second embodiment of the present invention. In FIG. 2, the same members as those shown in FIG. 1 are identified by the same reference numerals and the description thereof will be thus omitted herein.

As shown in FIG. 2A and as in the first embodiment, a buffer layer 12, an active layer 13, and a barrier layer 14 are first formed over a substrate 11 and a mask film 15 is formed in a region on the barrier layer 14 in which a gate electrode is to be formed

Next, as shown in FIG. 2B, an n-type GaN layer 21 doped with Si is formed on the barrier layer 14 by an MOCVD process.

Then, as shown in FIG. 2C, Al_{0.26}Ga_{0.74}N and GaN films are epitaxially grown alternately on the n-type GaN layer 21 seven times, i.e., seven Al_{0.26}Ga_{0.74}N films and seven GaN films are alternately grown, by an MOCVD process, thereby forming a multilayer film 16. Each Al_{0.26}Ga_{0.74}N film has a thickness of 5.6 nm and each GaN film has a thickness of 1.4 nm.

Subsequently, as shown in FIG. 2D, the mask film 15 is removed and an ohmic electrode 17 and a gate electrode 18 are formed in the same manners as in the first embodiment.

According to the semiconductor device fabrication method of this embodiment, since the multilayer film 16 is selectively formed only in the ohmic electrode 17 formation region, variations in the thickness of the barrier layer 14 under the gate electrode 18 can be suppressed. In addition, since the n-type GaN layer 21 is formed only between the multilayer film 16 and the barrier layer 14, the contact resistance of the ohmic electrode 17 can be reduced further. Moreover, the n-type GaN layer 21 does not remain under the gate electrode 18, whereby increase in gate leakage current is prevented.

### Third Embodiment

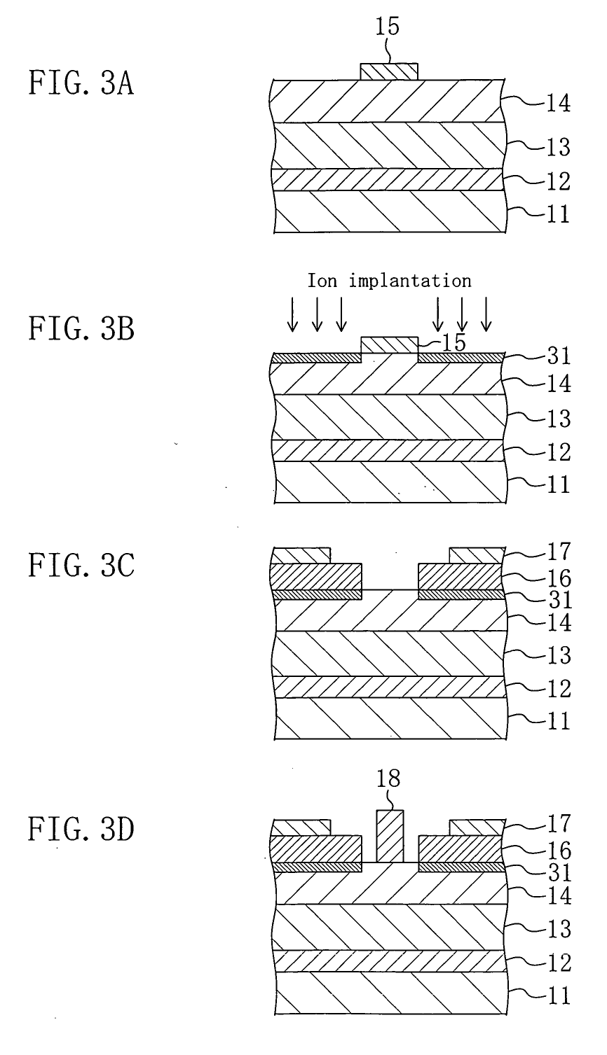

A third embodiment of the present invention will be described with reference to the accompanying drawings. FIG. 3 illustrates process steps for fabricating a semiconductor device according to the third embodiment of the present invention. In FIG. 3, the same members as those shown in FIG. 1 are identified by the same reference numerals and the description thereof will be thus omitted herein.

As shown in FIG. 3A and as in the first embodiment, a buffer layer 12, an active layer 13, and a barrier layer 14 are first formed over a substrate 11 and a mask film 15 is formed in a region on the barrier layer 14 in which a gate electrode is to be formed.

Next, as shown in FIG. 3B, ions of Si are implanted into the near-surface region in the barrier layer 14 with the mask film 15 used as an implantation mask. In this process, the ion-accelerating voltage is preferably set low so that the impurity concentration is high at the upper surface of the barrier layer 14. Thereafter, a heat treatment is performed to activate the implanted ions, thereby forming an n-type doped layer 31. It should be noted that the heat treatment may be omitted and the implanted ions may be activated by a heat treatment which is carried out in a subsequent epitaxial growth process.

Then, as shown in FIG. 3C, Al_{0.26}Ga_{0.74}N and GaN films are epitaxially grown alternately on the n-type doped layer 31 seven times, i.e., seven Al_{0.26}Ga_{0.74}N films and seven GaN films are alternately grown, by an MOCVD process, thereby forming a multilayer film 16. Each Al_{0.26}Ga_{0.74}N film has a thickness of 5.6 nm and each GaN film has a thickness of 1.4 nm.

Subsequently, as shown in FIG. 3D, the mask film 15 is removed and an ohmic electrode 17 and a gate electrode 18 are formed in the same manners as in the first embodiment.

According to the semiconductor device fabrication method of this embodiment, since the use of the mask film 15 enables the multilayer film 16 to be selectively formed only in the ohmic electrode 17 formation region, variations in the thickness of the barrier layer 14 under the gate electrode 18 can be suppressed. In addition, since the n-type doped layer 31 is formed only between the multilayer film 16 and the barrier layer 14, the contact resistance of the ohmic electrode 17 can be reduced further without causing any increase in leakage current from the gate electrode 18. Moreover, since the mask film 15 functions as an ion-implantation mask and as a film-growing mask, almost no increase is required in the number of process steps as compared with typical semiconductor device fabrication methods.

### Fourth Embodiment

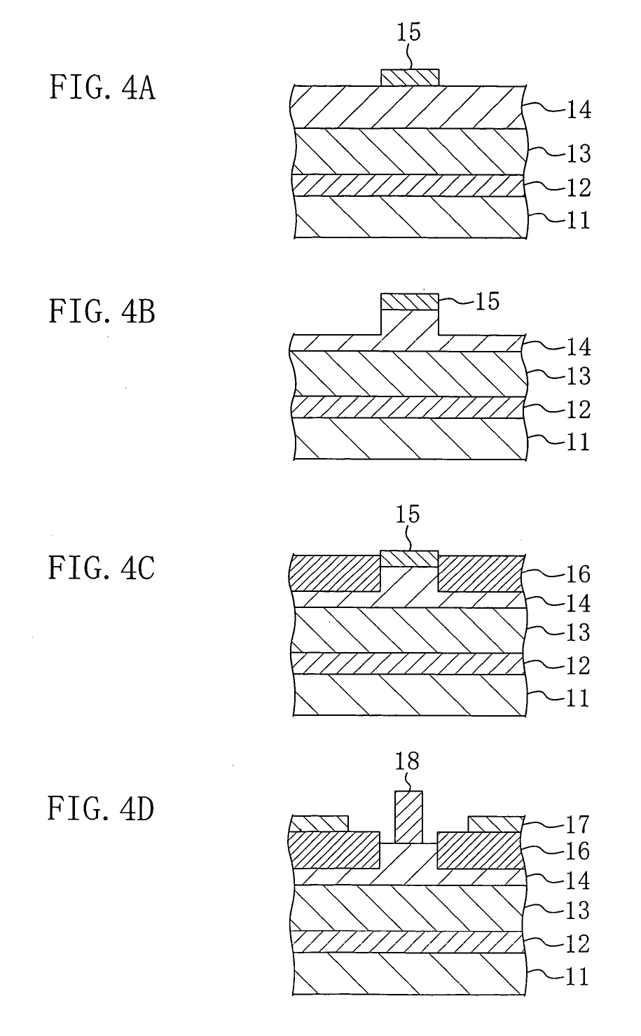

A fourth embodiment of the present invention will be described with reference to the accompanying drawings. FIG. 4 illustrates process steps for fabricating a semiconductor device according to the fourth embodiment of the present invention. In FIG. 4, the same members as those shown in FIG. 1 are identified by the same reference numerals and the description thereof will be thus omitted herein.

As shown in FIG. 4A and as in the first embodiment, a buffer layer 12, an active layer 13, and a barrier layer 14 are first formed over a substrate 11 and a mask film 15 is formed in a region on the barrier layer 14 in which a gate electrode is to be formed.

Next, as shown in FIG. 4B, temperature in the MOCVD chamber is raised to about 1050° C. in a hydrogen gas atmosphere, thereby selectively etching part of the barrier layer 14 which is not covered with the mask film 15.

Then, as shown in FIG. 4C, a multilayer film 16 is formed in the same chamber without exposing the etched barrier layer 14 to the atmosphere. The multilayer film 16 is composed of Al_{0.26}Ga_{0.74}N and GaN films stacked alternately seven times by epitaxial growth. Each of the seven Al_{0.26}Ga_{0.74}N films has a thickness of 5.6 nm and each of the seven GaN films has a thickness of 1.4 nm. In this manner, the etching of the barrier layer 14 and the regrowth of the multilayer film 16 are successively performed in the same chamber without exposure to the atmosphere, whereby the interface between the barrier layer 14 and the multilayer film 16 can be kept in good condition. The etching of the barrier layer 14 may be performed by plasma etching using a chlorine-based gas.

Subsequently, as shown in FIG. 4D, the mask film 15 is removed using buffered HF or the like and then an ohmic electrode 17 and a gate electrode 18 are formed as in the first embodiment.

According to the semiconductor device fabrication method of this embodiment, not only the multilayer film 16 is selectively formed only in the ohmic electrode 17 formation region, but also the thickness of the barrier layer 14 is reduced in the ohmic electrode 17 formation region. This allows the contact resistance of the ohmic electrode 17 to be reduced further. Moreover, since the etching of the barrier layer 14 can be performed using the MOCVD chamber with the mask film 15 used as a mask, almost no increase is required in the number of process steps.

In etching the barrier layer 14, it is preferable that part of the barrier layer 14 is left so that the active layer 13 is not exposed. By leaving the part of the barrier layer 14, 2DEG is generated also at the interface between the active layer 13 and the barrier layer 14 under the multilayer film 16 and the potential barrier at the interface between the multilayer film 16 and the barrier layer 14 is reduced. This enables the ohmic electrode 17 to come into contact with the channel with low resistance.

In this embodiment, the thickness of part of the barrier layer 14 located in the multilayer film 16 formation region is reduced by etching the barrier layer 14. Instead, the thickness of part of the barrier layer 14 located in the gate electrode 18 formation region may be increased. For example, an AlGaN layer whose thickness is as small as or smaller than about 5 nm may be formed on the active layer 13, and then the AlGaN layer may be regrown only in the gate electrode 18 formation region to form the barrier layer 14. In this case, since etching of the barrier layer 14 is not necessary, the barrier layer 14 with no crystal defects is obtained, thereby preventing characteristic deterioration.

As described above, the semiconductor devices and their fabrication methods according to the present invention produce the effect of realizing semiconductor devices in which a multilayer film composed of aluminum gallium nitride layers and gallium nitride layers is used as a contact layer and therefore the contact resistance is small and variations in characteristic values such as threshold voltage are small. The inventive devices and methods are thus effective as transistors that are used as Group III-V nitride semiconductor devices, particularly as high-frequency devices, and as their fabrication methods.

What is claimed is:

1. A method for fabricating a semiconductor device, comprising the steps of:
(a) forming a first semiconductor layer made of a first nitride semiconductor over a substrate;
(b) selectively forming, on the first semiconductor layer, a mask film covering part of the upper surface of the first semiconductor layer;
(c) selectively forming, on the first semiconductor layer, a multilayer film with the mask film used as a formation mask, the multilayer film including stacked second and third nitride semiconductors having different band gaps; and
(d) forming an ohmic electrode on the multilayer film.

2. The method of claim 1, wherein the mask film is a single layer film made of one compound selected from the group consisting of silicon dioxide, silicon oxynitride, and silicon nitride or a multilayer film in which two or more compounds selected from the group are stacked.

3. The method of claim 1, further comprising:
the step of removing the mask film to expose the part of the upper surface of the first semiconductor layer, after the step (c) is performed; and
the step of forming a Schottky electrode on the exposed part of the upper surface of the first semiconductor layer.

4. The method of claim 1, further comprising:
between the step (b) and the step (c), the step of selectively forming, on the first semiconductor layer, a second semiconductor layer made of an n-type doped fourth nitride semiconductor, with the mask film used as a formation mask.

5. The method of claim 1, further comprising:
between the step (b) and the step (c), the step of selectively implanting ions of an n-type impurity into the first semiconductor layer with the mask film used as an implantation mask; and
the step of performing a heat treatment for activating the implanted n-type impurity ions.

6. The method of claim 5, wherein the n-type impurity is silicon.

7. The method of claim 1, further comprising:
between the step (b) and the step (c), the step of selectively etching the first semiconductor layer with the mask film used as an etching mask, thereby forming a recess in an upper portion in the first semiconductor layer,
wherein in the step (c), the multilayer film is formed on the bottom of the recess.

8. The method of claim 1, further comprising:
the step of forming, over the substrate, a third semiconductor layer made of a fifth nitride semiconductor whose band gap is smaller than that of the first nitride semiconductor, before the step (a) is performed,
wherein in the step (a), the first semiconductor layer is formed on the third semiconductor layer.

9. A semiconductor device, comprising:
a substrate;
a first semiconductor layer made of a first nitride semiconductor and formed over the substrate:
a Schottky electrode formed in a region on the first semiconductor layer;
a multilayer film formed in a region on the first semiconductor layer which is different from the Schottky electrode formation region and including stacked second and third nitride semiconductors having different band gaps; and
an ohmic electrode formed on the multilayer film,
wherein an n-type impurity concentration at an interface between the first semiconductor layer and the multilayer film is higher than that at a contact surface between the first semiconductor layer and the Schottky electrode.

10. The semiconductor device of claim 9, wherein two such multilayer films are formed so as to be respectively located at both sides of the Schottky electrode;
the ohmic electrode is formed on each of the multilayer films; and
the semiconductor device functions as a field effect transistor.

11. The semiconductor device of claim 9, further comprising a second semiconductor layer formed in contact with the lower surface of the first semiconductor layer and made of a fourth nitride semiconductor whose band gap is smaller than that of the first nitride semiconductor.

12. A semiconductor device, comprising:
a substrate;
a first semiconductor layer made of a first nitride semiconductor and formed over the substrate;
a Schottky electrode formed in a region on the first semiconductor layer;
a multilayer film formed in a region on the first semiconductor layer which is different from the Schottky electrode formation region and including stacked second and third nitride semiconductors having different band gaps; and
an ohmic electrode formed on the multilayer film,
wherein the thickness of part of the first semiconductor layer located under the ohmic electrode is smaller than the thickness of part of the first semiconductor layer located under the Schottky electrode.

13. The semiconductor device of claim 12, wherein two such multilayer films are formed so as to be respectively located at both sides of the Schottky electrode;
the ohmic electrode is formed on each of the multilayer films; and
the semiconductor device functions as a field effect transistor.

14. The semiconductor device of claim 12, further comprising a second semiconductor layer formed in contact with the lower surface of the first semiconductor layer and made of a fourth nitride semiconductor whose band gap is smaller than that of the first nitride semiconductor.
